(19) United States
(12) Patent Application Publication
(10) Pub. No.: US 2010/0039159 A1
(43) Pub. Date: Feb. 18, 2010

(54) CONTROL DEVICE AND CONTROL METHOD

(75) Inventors: Shoji Otaka, Yokohama-shi (JP); Toshiyuki Umeda, Inagi-shi (JP); Takafumi Sakamoto, Machida-shi (JP); Makoto Tsuruta, Kawasaki-shi (JP); Keisuke Mera, Kawasaki-shi (JP); Yu Kaneko, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/405,695

(22) Filed: Mar. 17, 2009

(30) Foreign Application Priority Data
Aug. 14, 2008 (JP) P2008-208841

(51) Int. Cl. H03K 17/00

(52) U.S. Cl. 327/365

(57) ABSTRACT

This control device includes: a rectifier to rectify a received signal; an amplifier having an amplifying element to amplify the signal rectified by the rectifier and an assisting element being connected to the amplifying element to assist the amplifying element; a determination unit to determine presence or absence of the signal amplified by the amplifier; and a controller to control the connection of the assisting element with the amplifying element at a predetermined timing.

### CROSS-REFERENCE TO RELATED APPLICATIONS

This application is based upon and claims the benefit of priority from the prior Japanese Patent Application No. 2008-208841, filed on Aug. 14, 2008; the entire contents of which are incorporated herein by reference.

### BACKGROUND OF THE INVENTION

1. Field of the Invention

The present invention relates to a control device and a control method generating a control signal based on, for example, a weak signal.

2. Description of the Related Art

A remote-control device and a control device controlling a home electric appliance such as a TV generally use a technique of optical communication being one-way communication. Specifically, the remote-control device emits an optical signal or the like, and the control device built in a TV obtains a control signal by receiving the optical signal and changing the signal into an electrical signal.

Such a remote-control device and control device consume so-called standby power since there is a need to constantly operate a light-receiving part of the control device. Further, since the light-receiving part is driven, when a regulator is provided in the control device, a power loss in the regulator becomes larger than power consumption of the light-receiving part itself, resulting that power consumption as a whole control device may become large.

Accordingly, it is proposed to drive the control device using batteries and directly use a signal obtained by rectifying a received wave for generating the control signal (refer to, for example, JP-A2005-295289 (KOKAI)). However, a rectifier rectifying the received wave generally has a low sensitivity, so that an amplifier is required to enhance the sensitivity of rectifier. The amplifier consumes electric power, which results in placing a burden on the batteries of the control device.

### BRIEF SUMMARY OF THE INVENTION

As described above, in the control device generating the control signal based on an instruction signal from the remote-control device, there is a problem that the power consumption of the whole control device (especially a receiving front-end including the amplifier) is increased when the sensitivity for receiving light or the like from the remote-control device is tried to be enhanced.

The present invention has been made to solve such problems, and an object thereof is to provide a control device and a control method capable of suppressing power consumption while enhancing a sensitivity for receiving a signal from a remote-control device.

In order to achieve the aforementioned object, a control device according to one aspect of the present invention includes: a rectifier to rectify a received signal; an amplifier having an amplifying element to amplify the signal rectified by the rectifier and an assisting element being connected to the amplifying element to assist the amplifying element; a determination unit to determine presence or absence of the signal amplified by the amplifier; and a controller to control the connection of the assisting element with the amplifying element at a predetermined timing.

Further, a control method according to another aspect of the present invention is a control method of a control device including a rectifier to rectify a received signal, an amplifier having an amplifying element to amplify the signal rectified by the rectifier and an assisting element being connected to the amplifying element to assist the amplifying element, a determination unit to determine presence or absence of the signal amplified by the amplifier, and a controller to control the connection of the assisting element with the amplifying element at a predetermined timing, the control method is characterized in that it includes: searching, with the controller, an optimum first connection number of the assisting element with the amplifying element for enhancing a sensitivity of the amplifier; controlling, with the controller, the connection number of the assisting element with the amplifying element to be the first connection number at the predetermined timing; and controlling, with the controller, the connection number of the assisting element with the amplifying element to be a second connection number other than the first connection number.

### BRIEF DESCRIPTION OF THE DRAWINGS

FIG. 1 is a view showing a configuration of a control device of one embodiment according to the present invention.

FIG. 2 is a circuit diagram showing a concrete example of the control device shown in FIG. 1.

FIG. 3 is a flow chart showing an operation of the control device according to this embodiment.

FIG. 4 is a circuit diagram showing a modified example of the control device shown in FIG. 2.

FIG. 5 is a view showing an operation of an amplifier according to this embodiment.

FIG. 6 is a view showing a correction operation of the amplifier according to this embodiment.

FIG. 7 is a view showing an example of an instruction signal to be transmitted by a remote-control device according to this embodiment.

FIG. 8 is a view showing an example of the instruction signal to be transmitted by the remote-control device according to this embodiment.

FIG. 9 is a view showing an example of the instruction signal to be transmitted by the remote-control device according to this embodiment.

FIG. 10 is a view showing an operation example of the amplifier of the control device according to this embodiment.

FIG. 11 is a view showing an example of data to be stored in a memory 65 according to this embodiment.

FIG. 12 is a flow chart showing another operation example of the control device according to this embodiment.

FIG. 13 is a flow chart showing an operation example of the amplifier of the control device according to this embodiment.

FIG. 14 is a view showing an operation example of the amplifier according to this embodiment.

FIG. 15 is a view showing a relation among an instruction signal and a correction operation, a high sensitivity state and a low sensitivity state in this operation example.

FIG. 16 is a view showing a relation among the instruction signal and the correction operation, the high sensitivity state and the low sensitivity state in this operation example.

FIG. 17 is a circuit diagram showing a concrete example of a control device according to another embodiment.

FIG. 18 is a view showing a circuit example of a charge transfer control section (CTC) in the control device shown in FIG. 17.

### DETAILED DISCRIPTION OF THE INVENTION

In a control device according to an embodiment of the present invention, a remote-control device transmits an instruction signal using a radio wave, and the control device receives the instruction signal and generates a control signal controlling a controlled object such as a TV. A medium for transmitting the instruction signal is not limited to the radio wave, and an optical signal such as infrared ray can also be used, for instance. The control device driven by batteries or the like rectifies the received instruction signal, determines presence/absence of the instruction signal, and outputs the control signal when the instruction signal is determined to exist.

The instruction signal is normally weak, so that if it is only rectified, it is difficult to obtain a signal whose magnitude is sufficient enough for the determination. Accordingly, the control device of this embodiment amplifies a rectified signal being the rectified instruction signal using an amplifier, and determines presence/absence of the instruction signal based on the magnitude of the amplified signal. However, when the amplifier is constantly in a high sensitivity state, the burden on the batteries which drive the control device becomes large, resulting that a continuous operation time of the control device itself is reduced. Accordingly, in the control device according to the embodiment of the present invention, by suppressing power consumption of the entire control device by controlling the state of amplifier, it is possible to perform control with high sensitivity and low power consumption.

Concretely, a system for changing the sensitivity of amplifier in a time division is realized. Namely, time is divided into a time with high sensitivity and a time with low sensitivity. Although the power consumption during the time in which the amplifier operates with high sensitivity is high, since it is configured that a shoot-through current is reduced during the time in which the amplifier operates with low sensitivity, the power consumption during the time is lowered. In the embodiment to be described hereinbelow, it is designed such that a time (time for correction operation) T_{c} during which the high sensitivity and the low sensitivity are recognized is provided at the time of initial setting after a power supply is turned on, the recognition is performed, and then, two states of high sensitivity time T_{H} and low sensitivity time T_{L} are periodically operated.

### First Embodiment

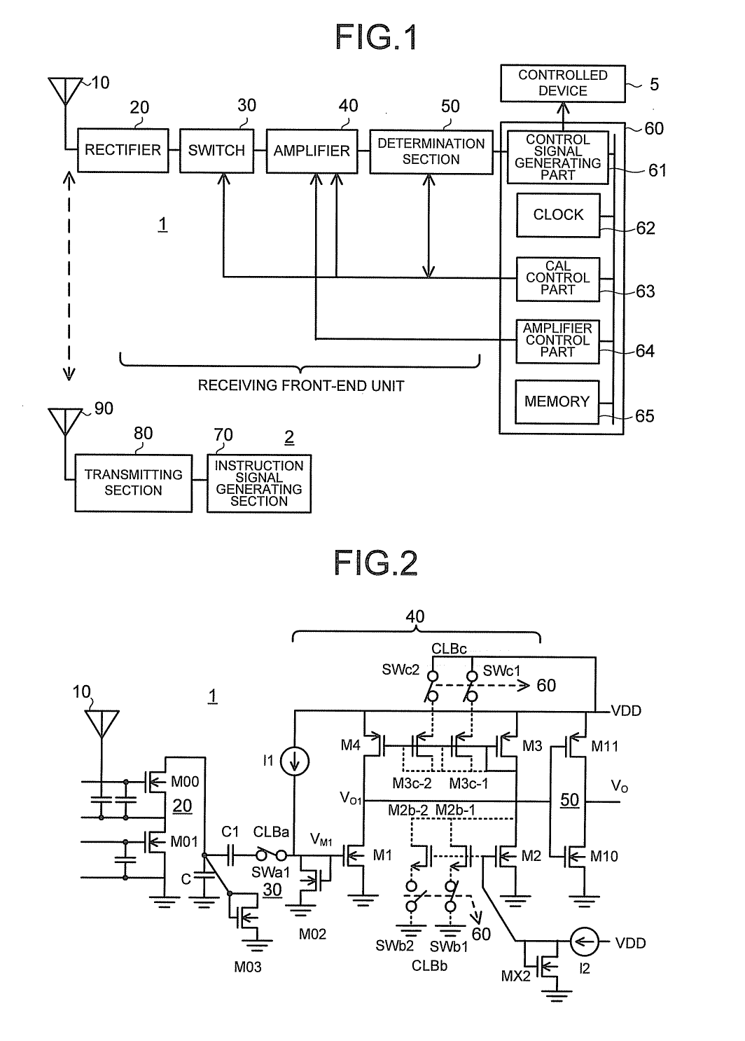

Hereinafter, one embodiment of the present invention will be described in detail with reference to the drawings. As shown in FIG. 1, a control device 1 according to this embodiment includes: an antenna section 10 receiving a signal from a remote-control device 2; a rectifier 20 rectifying the signal received by the antenna section 10; an amplifier 40 amplifying the rectified signal; a determination section 50 determining presence/absence of an instruction signal based on a magnitude of the amplified signal; and a control section 60 generating a control signal based on a determination result made by the determination section 50. Further, between an output of the rectifier 20 and an input of the amplifier 40, a switch section 30 performing opening/closing operation based on an instruction from the control section 60 is provided.

The remote-control device 2 includes: an instruction signal generating section 70 generating the instruction signal; a transmitting section 80 transmitting the generated instruction signal to the control device 1; and an antenna section 90.

The antenna section 10 receives the instruction signal from the remote-control device 2. For the antenna section 10, the one suitable for the medium with which the remote-control device 2 transfers the instruction signal can be used. For example, if the remote-control device 2 transmits the instruction signal using a radio wave, the antenna section 10 becomes an antenna for receiving the radio wave, and if the remote-control device 2 transmits the instruction signal using light such as infrared ray, the antenna section 10 can be realized by a light-receiving element or the like.

The rectifier 20 is a functional element having a rectification action, and a semiconductor element such as a diode and a transistor can be used, for instance. Since the rectifier 20 rectifies a weak signal received by the antenna section, it is preferably a low-loss rectifier.

In an example shown in FIG. 2, the rectifier 20 includes n-type MOSFETs connected in series (hereinafter, “M00” and “M01”), and uses the rectification action of the MOSFETs. At a connection point between M00 and M01, an output of the antenna section 10 is connected via a capacitor, and a rectified signal is output from a drain of M00 via a capacitor C1. The capacitor C1 operates to take out an amount of change in the output of the rectifier 20.

The amplifier 40 amplifies the signal rectified by the rectifier. The amplifier 40 has a function of enhancing an accuracy of determination (enhancing a sensitivity of determination) made by the determination section 50 by correcting a strength and weakness (correcting a variation) of the instruction signal due to variation of elements in production. A timing at which the variation is corrected is controlled by the control section 60.

As shown in FIG. 2, the amplifier 40 includes a p-type MOSFET (hereinafter, referred to as “M4”) and an n-type MOSFET (similarly, “M1”) whose drains are connected with each other, and a p-type MOSFET (similarly, “M3”) and an n-type MOSFET (similarly, “M2”) whose drains are connected with each other. Sources of M4 and M3 and sources of M1 and M2 are connected to power supply VDD and a ground, respectively. At a gate of M1, a current source I1 is connected. At a gate of M2, a current source I2 is connected. A gate and a drain of an n-type MOSFET (M02) whose source is grounded are connected to the gate of M1, and M02 and M1 cooperate to configure a current mirror circuit. A drain and a gate of an n-type MOSFET (MX2) whose source is grounded are connected to the gate of M2.

Since the current source I1 is provided, a threshold voltage necessary for M1 to operate is applied to M1. Accordingly, the sensitivity is increased. What is adjusted is a voltage of Vₒ₁, and a magnitude of current flowing through an inverter formed of M10 and M11 less than a current flowing through M02, M2 and M1. Therefore, by performing a time division operation of the sensitivity using the present circuits, it is possible to remarkably reduce the power consumption.

The rectified output of the rectifier 20 is input into an input of the current mirror circuit formed of M02 and M1 (gate of M1), and output from the drain of M1 as a current. A gate of M4 is connected to a gate of M3. The gate of M2 is biased. As a result, an amplified output voltage Vₒ₁ is generated at a connection point between M4 and M1. Note that a capacitor C whose one end is grounded operates to stabilize a voltage V_{M1} generated due to an input-output characteristic of M02. At the other end of the capacitor C, a drain and a gate of an n-type MOSFET (M03) whose source is grounded are connected.

If there is no input into the antenna section 10, a gate voltage V_{M1} of M1 becomes basically a threshold voltage. A current I2 is copied to M4 by current mirrors MX2 to M2 and M3 to M4. If no element variance exists in the transistors forming the current mirrors, the current flowing through M1 and the current flowing through M4 become substantially the same, and Vₒ₁ takes a voltage of about VDD/2. When the current sources I1 and I2 are not provided, the gate voltage V_{M1} of M1 becomes a ground potential, but, if a fine CMOS is applied, a leakage current is flown when a voltage is applied between the drain and the source. This current results in an input offset, so that there is a need to introduce a mechanism to offset the leakage current to enhance the sensitivity. M2 operates to generate a leakage current which simulates the leakage current flown through M1 when no signal is input into the antenna section 10. M3 and M4 form a current mirror circuit, and a current which compensates the leakage current of M1 is output from M4. Accordingly, Vₒ₁ becomes a voltage of about VDD/2 when no signal is input.

In this embodiment, the amplifier 40 further includes a circuit which fine-adjusts an offset caused by a variation of element characteristics of M1 to M4. Namely, as shown in FIG. 2, the amplifier 40 further includes p-type MOSFETs M3_{c-1} to M3_{c-2} connected in parallel with M3, and n-type MOSFETs M2_{b-1} to M2_{b-2} connected in parallel with M2. It is configured that each source of M3_{c-1} to M3_{c-2} and M2_{b-1} to M2_{b-2} can be cut off by switches SW_{c1} to SW_{c2} and SW_{b1} to SW_{b2}, and the control section 60 can control the parallel connection number. Note that the parallel connection number of M3_{c-1} to M3_{c-2} and that of M2_{b-1} to M2_{b-2} are two at maximum in FIG. 2, but, it is not limited to this. The number can be increased/decreased in accordance with the offset adjustment amount. In a final state where the adjustment is completed, the output Vo takes a middle value (VDD/2) between H (VDD) and L (GND).

The determination section 50 determines presence/absence of the instruction signal based on the output signal of the amplifier 40. In an example shown in FIG. 2, the determination section 50 has an inverter including a p-type MOSFET (similarly, “M11”) and an n-type MOSFET (similarly, “M10”) whose drains are connected with each other. Sources of M11 and M10 are respectively connected to the power supply VDD and the ground. The output of the amplifier 40, which is, the voltage Vₒ₁ shown in FIG. 2 is connected to gates of M11 and M10. When the antenna section 10 is in a state where no signal is input therein, the gate of M1 takes a voltage in the vicinity of the threshold voltage. If it designed such that the current flown through M4 becomes smaller than the current flown through M1 by the setting of a current mirror formed of MX2 to M2, M2_{b-1} and M2_{b-2} and a current mirror formed of M3, M3_{c-1} and M3_{c-2} to M4, Vₒ₁ takes a value in the vicinity of VDD. At this time, the determination section 50 formed of M11 and M10 outputs L being inverted VDD. Meanwhile, when a signal is input into the antenna section 10, the gate of M1 takes a voltage higher than the threshold voltage, and Vₒ₁ becomes the ground potential. As a result, the output Vo of the determination section 50 becomes H. In a case of I1=I2=0 (zero) and when no signal is input, the gate of M1 takes a value of the ground, and M1 is turned off. If it is supposed that sizes are determined so that the leakage current from M4 is set to be larger than that of M1, Vₒ₁ in this case becomes VDD, and the determination section 50 formed of M11 and M10 outputs L being inverted VDD. Meanwhile, when a signal is input into the antenna section 10, M1 is turned on, and Vₒ₁ becomes the ground potential. As a result, the output Vo of the determination section 50 becomes H.

The switch section 30 is inserted between the rectifier 20 and the amplifier 40. The switch section 30 cuts-off a signal to be input from the rectifier 20 to the amplifier 40, and enables the offset adjustment of the amplifier 40. As described above, the amplifier 40 has the circuit to adjust the offset caused by the variation of elements, but, the adjustment cannot be correctly performed in a state where the input signal exists. The switch section 30 cuts-off the input to the amplifier 40 at the time of such offset adjustment (calibration). Note that the opening/closing operation of the switch section 30 is controlled by the control section 60.

The control section 60 has a function of controlling the offset adjustment of the amplifier 40 as well as controlling a gain adjustment of the amplifier 40. The control section 60 includes a control signal generating part 61 generating a control signal based on the determination result made by the determination section 50, a clock 62 giving a control timing, a calibration control part 63 (CAL control part) controlling the offset adjustment of the amplifier 40, an amplifier control part 64 controlling the gain adjustment of the amplifier 40, and a memory 65 storing a timing of the offset adjustment and the gain adjustment and the like. The control section 60 is realized by a CPU, a memory or the like. Note that the memory 65 can store not only operation procedures of the CAL control part 63 and the amplifier control part 64 but also the states of switches SW_{b1} to SW_{b2} and SW_{c1} to SW_{c2} shown in FIG. 2.

The remote-control device 2 includes the instruction signal generating section 70, the transmitting section 80 and the antenna section 90. The instruction signal generating section 70 is connected to a not-shown input section, and generates a predetermined instruction signal based on an instruction from a user. The transmitting section 80 generates a transmitting signal by modulating a high-frequency signal or the like according to the generated instruction signal. The antenna section 90 transmits the transmitting signal generated by the transmitting section 80. The transmitting section 80 and the antenna section 90 can be changed in accordance with a medium for transmitting the instruction signal. For instance, if an infrared ray is used, the transmitting section 80 and the antenna section 90 can be realized by being combined with an infrared-emitting diode or the like.

The remote-control device 2 transmits an ID signal corresponding to the control device as an instruction signal. When the ID signal from the remote-control device 2 transmitted as the instruction signal is the same as an ID of the control device, and power supply of a controlled device 5 is cut off, the control device 1 generates a control signal to release the cut-off state of the power supply, and supplies power to the controlled device 5. Meanwhile, when the transmitted ID signal is the same as the ID of the control device, and the controlled device 5 is already operated, the control device 1 turns off the power supply of the controlled device 5 and generates, at the same time, a control signal to cut off the power supply.

Next, an operation example of a control device according to this embodiment will be explained.

The control device according to this embodiment repeats three operating states of (1) correction operation (calibration operation), (2) high sensitivity operation and (3) low sensitivity operation, and stands ready to receive the instruction signal from the remote-control device 2. Specifically, by repeating the high sensitivity operation with high sensitivity and large power consumption, and the low sensitivity operation with inferior sensitivity yet suppressed power consumption, the power consumption as a whole is suppressed.

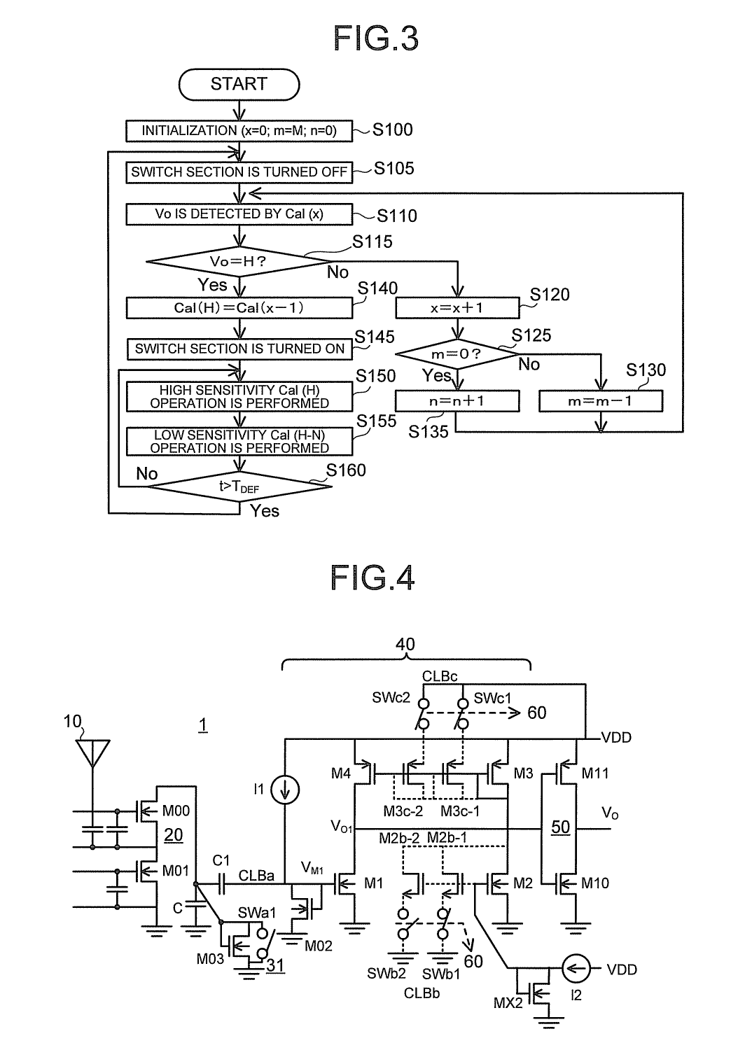

As shown in FIG. 3, the CAL control part 63 initializes the memory 65 (step 100, hereinafter, referred to as “S100”). In an initial state, the sensitivity of amplifier 40 is set to be in a low state (low sensitivity state). For example, all of the switches SW_{b1} to SW_{b2} are turned on so that the connection number of M2_{b-1} to M2_{b-2} connected in parallel with M2 is made to be a maximum number (here, parallel number is set as M), and all of the switches SW_{c1} to SW_{c2} are turned off so that the connection number of M3_{c-1} to M3_{c-2} connected in parallel with M3 is made to be zero (namely, a state where only M3 exists is created). The initialized memory 65 stores initial states of respective switches of the amplifier 40 shown in FIG. 2. In this example, a connection number m of the switches SW_{b1} to SW_{b2} and a connection number n of the switches SW_{c1} to SW_{c2} are set as M and zero, respectively, and the initial states are stored by being corresponded to an initial value zero of a variable x.

When the memory 65 is initialized, the CAL control part 63 turns off the switch section 30 (S105). By turning off the switch section 30, the amplifier 40 is made to be in a state where no signal is input therein. This state is suitable for correcting the offset caused by the variation of M1 to M4. Note that although a switch SWₐ₁ is serially connected between the rectifier 20 and the amplifier 40 in an example shown in FIG. 2, the switch section 30 may also be connected so as to short-circuit the input to the amplifier 40 or to short-circuit the voltage between the drain and the source of M03 inside the rectifier (output of the rectifier). In this case, when the switch section is turned on, the amplifier 40 can be made in a state where no signal is input therein. FIG. 4 shows a modified example in which a switch section 31, instead of the switch section 30, is provided to the output of the rectifier. Also in such a modified example, the amplifier 40 can be made in a state where no signal is input therein.

When the switch section 30 is turned off, the CAL control part 63 detects the determination result made by the determination section 50 (S110). As a result of detection, when the output Vo of the determination section 50 is not H (No in S115), the CAL control part 63 adds 1 to the variable x (S120), and detects whether or not the connection number m of the switches SW_{b1} to SW_{b2} is zero (S125). If m is not zero (No in S125), one of the switches SW_{b1} to SW_{b2} is turned off to thereby decrease the connection number m of M2_{b-1} to M2_{b-2} by one, and if m is zero (Yes in S125), 1 is added to the connection number n of M3_{c-1} to M3_{c-2} (S135). Specifically, if the determination result made by the determination section 50 is not H, the sensitivity of amplifier 40 does not reach the maximum, so that the connection number m of M2_{b-1} to M2_{b-2} where the parallel connection number is the maximum in the initial state is decreased by one. Meanwhile, if the connection number m of M2_{b-1} to M2_{b-2} is zero, which means a state where only M2 exists, so that at this time, the connection number of M3_{c-1} to M3_{c-2} is increased by one. In this manner, a processing is conducted in which the connection number m of M2_{b-1} to M2_{b-2} is decreased, and after m becomes zero, the connection number n of M3_{c-1} to M3_{c-2} is increased until the output Vo of the determination section 50 becomes H.

After increasing/decreasing the connection number m of M2_{b-1} to M2_{b-2} and/or the connection number n of M3_{c-1} to M3_{c-2}, the CAL control part 63 detects the determination result made by the determination section 50 again (S110). When the output Vo of the determination section 50 is not H, steps 120 to 135 are repeated (No in S115).

When the output Vo of the determination section 50 is H (Yes in S115), the CAL control part 63 stores the connection number m of M2_{b-1} to M2_{b-2} and the connection number n of M3_{c-1} to M3_{c-2} corresponding to the state where the variable x is decreased by one, in the memory 65 as a high sensitivity state. Namely, by setting the state right before the output Vo of the determination section 50 becomes H as the high sensitivity state, the CAL control part 63 stores the corresponding connection number m of M2_{b-1} to M2_{b-2} and connection number n of M3_{c-1} to M3_{c-2} (S140).

In addition, by setting a state with lower sensitivity than the high sensitivity state made by the connection number m of M2_{b-1} to M2_{b-2} and the connection number n of M3_{c-1} to M3_{c-2} as a low sensitivity state, the CAL control part 63 stores the corresponding connection number of M2_{b-1} to M2_{b-2} and connection number of M3_{c-1} to M3_{c-2}. In examples shown in FIG. 2 and FIG. 3, if a value of variable corresponding to the high sensitivity state is x, a connection number of M2_{b-1} to M2_{b-2} and a connection number of M3_{c-1} to M3_{c-2} in which the value of variable becomes x−N (N is an integer) are stored as the low sensitivity state. Concretely, if the connection number n remains zero, the low sensitivity state corresponds to a state where the connection number m is set as the connection number to which N is added, and if the connection number m is zero, the low sensitivity state corresponds to a state where the connection number n is set as the connection number from which N is subtracted.

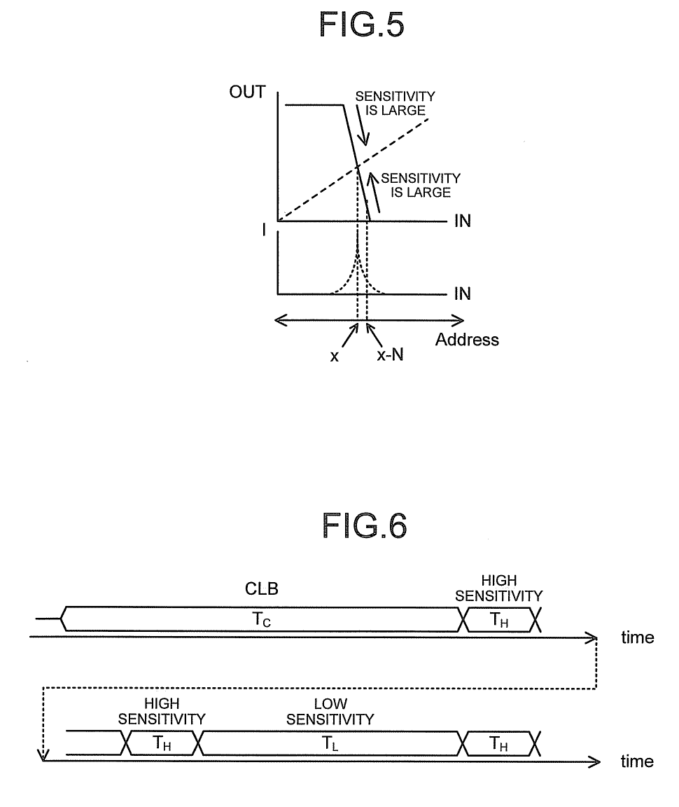

FIG. 5 shows this state. When the parallel connection number of MOSFETs to M2 and M3 is increased/decreased, the bias is increased/decreased according thereto, resulting that an input-output characteristic of the amplifier 40 is changed (solid line in an upper stage in FIG. 5). Here, when the sensitivity of amplifier 40 shown in FIG. 2 becomes the maximum is when the voltage is in a state where its input and output are equal (upward-sloping dashed line in an upper graph in FIG. 5). At this time, the current I becomes the maximum. Accordingly, in the aforementioned correction operation, an operation to approximate to an intersection point between the upward-sloping dashed line and the input-output characteristic is performed by increasing/decreasing the connection number of M2_{b-1} to M2_{b-2} and the connection number of M3_{c-1} to M3_{c-2}. As a result, as shown by a dashed line in a lower graph of FIG. 5, a state with high sensitivity (peak state) is searched, and the variable x at this time and the connection numbers m and n corresponding thereto are stored in the memory 65 as a combination of high sensitivity state. In order to create a low sensitivity state, it is only required to create a state shifted from the peak of high sensitivity state. Therefore, as shown in FIG. 5, by previously storing the connection numbers m and n corresponding to the state where a predetermined number N is subtracted from the value of variable x corresponding to the state of high sensitivity in the memory 65, and by using the combination, the low sensitivity state can be realized.

Operations from S105 through S140 correspond to the aforementioned correction operation. Though this correction operation, a combination of switches SWb and SWc making the state of high sensitivity where the offset caused by a variation between the elements of M1 to M4 is removed, and the state of low sensitivity where the sensitivity is lower than that in the high sensitivity state to suppress the power consumption, can be stored in the memory.

Subsequently, the CAL control part 63 turns on the switch section 30 (S145). Accordingly, the rectifier 20 and the amplifier 40 are connected, and the control device 1 becomes a receiving state.

When the CAL control part 63 turns on the switch section 30, the amplifier control part 64 reads the connection numbers m and n making the state of high sensitivity from the memory 65, controls the corresponding switches SW_{b1} to SW_{b2} and SW_{c1} to SW_{c2} of the amplifier 40, and maintains the state for a predetermined period of time T_{H} (S150). The predetermined period of time T_{H} can be decided by the amplifier control part 64 based on a time signal from the clock 62.

Next, the amplifier control part 64 reads the connection numbers m and n making the state of low sensitivity from the memory 65, controls the corresponding switches SW_{b1} to SW_{b2} and SW_{c1} to SW_{c2} of the amplifier 40, and maintains the state for a predetermined period of time T_{L} (S155). The predetermined period of time T_{L} can also be decided by the amplifier control part 64 based on the time signal from the clock 62.

After the predetermined period of time T_{L} elapses, the amplifier control part 64 determines how much time has elapsed since the CAL control part 63 completed the correction operation (how much time has elapsed since the processing was received from the CAL control part 63) (S160). As a result of determination, if a predetermined period of time T_{DEF} has not elapsed (No in S160), the amplifier control part 64 reads the connection numbers m and n making the state of high sensitivity from the memory 65, and maintains the state for the predetermined period of time T_{H} (S150). Namely, until the predetermined period of time T_{DEF} elapses, the high sensitivity state and the low sensitivity state are alternately repeated (S150 through S160).

When the predetermined period of time T_{DEF} has elapsed (Yes in S160), the amplifier control part 64 returns the processing to the CAL control part 63, and resumes the correction operation (S105).

In this example, the correction operation is repeated each time the predetermined period of time T_{DEF} elapses, so that even when the variation between the elements M1 to M4 is large due to the surrounding temperature change, it is possible to maintain the high sensitivity state. If there is a situation where a surrounding situation is stable and the correction operation is required to be conducted only when, for instance, the power supply is turned on, it is possible to omit step 160 and repeat only steps 150 and 155 after conducting the correction operation at steps 105 to 145.

FIG. 6 shows an operation of the control device 1 shown in FIG. 3. Specifically, the correction operation is first executed for a period of time T_{C}, and thereafter, the high sensitivity operation for a period of time T_{H} and the low sensitivity operation for a period of time T_{L} are repeated.

As described above, according to the control device of this embodiment, since the high sensitivity state and the low sensitivity state are alternately repeated, it is possible to substantially suppress the power consumption in a state including the high sensitivity state. Further, since the correction operation is conducted prior to the operation in the high sensitivity state, it is possible to set a higher-sensitivity and more appropriate state of power consumption as the high sensitivity state.

Here, a relation among the instruction signal to be transmitted by the remote-control device 2 and respective operations in the high sensitivity state and the low sensitivity state of the control device 1 will be described. Since two operating states of the high sensitivity state and the low sensitivity state exist in the control device according to this embodiment, it is possible to suppress power consumption also at the remote-control device side in accordance with a distance between the remote-control device and the control device.

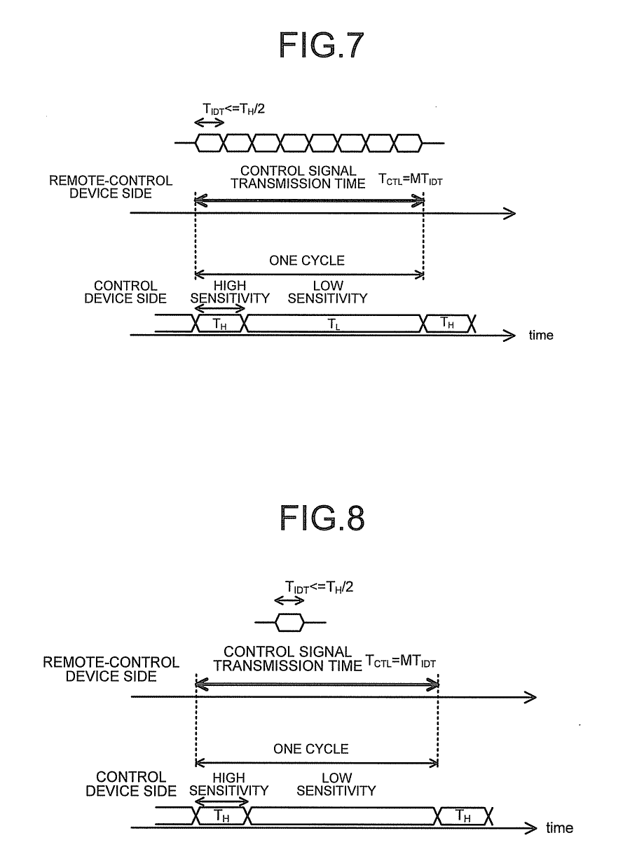

For instance, when the distance between the remote-control device and the control device is relatively long, there is a possibility that the control device cannot receive the instruction signal correctly unless it receives the signal in the high sensitivity state. Meanwhile, since the high sensitivity state and the low sensitivity state are alternately operated as described above, when a transmission distance is long, there is a need that the instruction signal reaches during the period of time T_{H} in the high sensitivity state. FIG. 7 shows an example of such a case where the transmission distance is long. If it is set that a transmission time of the instruction signal per unit is T_{IDT}, and T_{IDT}≦T_{H}/2 is satisfied, a control signal transmission time T_{CTL} (=M·T_{IDT}) is required for an amount of time corresponding to one cycle of the high sensitivity state and the low sensitivity state (T_{H}+T_{L}).

Meanwhile, when the distance between the remote-control device and the control device is short, the control device does not always have to be in the high sensitivity state. Namely, as shown in FIG. 8, if the instruction signal is transmitted for a period of time as long as T_{IDT} being the transmission time of the instruction signal per unit, the control device can receive the instruction signal.

Accordingly, in order to reduce the power consumption at the remote-control device side, it is only required to provide a timer to the instruction signal generating section 70 and to enable to switch the transmission time of the instruction signal. For instance, “sensitivity switching switch” is provided to the remote-control device 2, and it is configured that the instruction signal is transmitted for a period of time T_{H}+T_{L} when the sensitivity is set as high sensitivity, and the instruction signal is transmitted for a period of time T_{IDT} when the sensitivity is set as low sensitivity. With such a configuration, it is possible to minimize the instruction signal transmission time transmitted by the remote-control device, resulting that the power consumption at the remote-control device side can also be reduced.

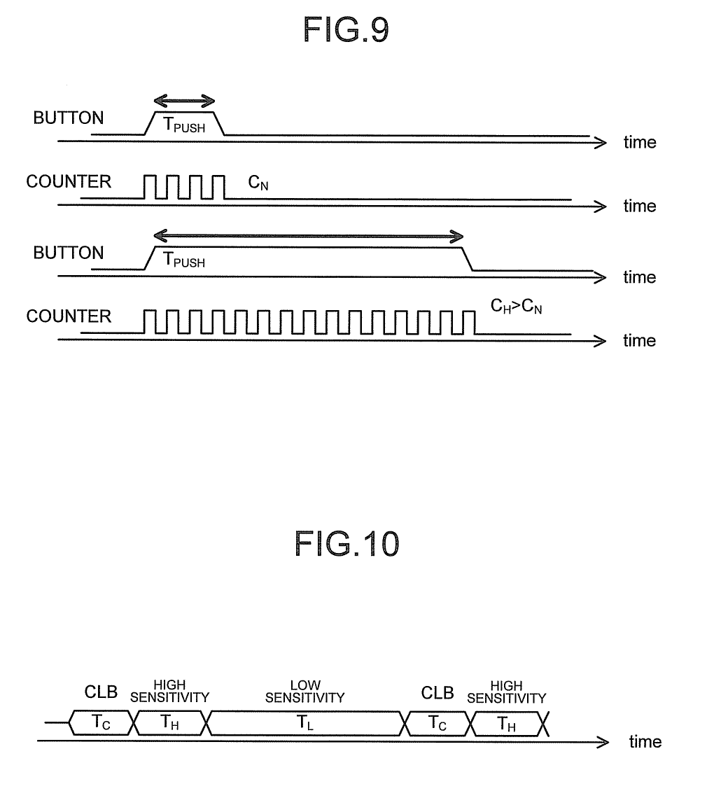

As another method of suppressing the power consumption at the remote-control device side, it is also possible to control the instruction signal transmission time in accordance with a time during which a user pushes a button or the like. For instance, a counter is provided to the instruction signal generating section 70 of the remote-control device, and a time during which the user pushes a button or the like is measured. Subsequently, the instruction signal transmission time may be decided in accordance with the obtained time. FIG. 9 shows an example of an instruction signal to be transmitted through such a configuration. If a time T_{PUSH} during which a button is pushed is short (upper stage), a counter C_{N} gives a small number, and if T_{PUSH} is long (lower stage), the counter C_{N} gives a large number. Subsequently, if it is configured such that when the given count value is equal to or smaller than a predetermined threshold value, the sensitivity becomes low sensitivity and when it is larger than the threshold value, the sensitivity becomes high sensitivity, it is possible to provide a remote-control device with high convenience which realizes a minimum instruction signal transmission time.

Here, a further detailed description will be made regarding a condition of the instruction signal to be transmitted by the remote-control device 2 and the power consumption. If a period of time during which the remote-control device transmits an ID as an instruction signal is set as T_{IDT}, a condition under which an ID signal is always received during the time T_{H} in high sensitivity is to satisfy T_{IDT}<T_{H}/2 and to transmit a signal whose cycle is T_{IDT} for one cycle (T_{CTL}) in which a time with low gain and that with high gain are combined. FIG. 7 and FIG. 8 also show conditions of such T_{IDT}, T_{H} and T_{CTL}. T_{CTL}/T_{IDT} is M (M is integer).

If a system in which transmission power of remote-control is 10 dBm, the power consumption of control device 1 during the time of low sensitivity and the time of high sensitivity are respectively 0.1 μW and 0.5 μW, T_{CTL} is 1 ms and T_{H} is 0.1 ms, is tentatively assumed, the control device 1 reduces energies as much as 0.9 ms×0.4 μW=0.36 nWs per 1 ms with the use of the time-division sensitivity control. Specifically, the power consumption of 0.36 μW is reduced.

Meanwhile, if an efficiency of a remote-control transmitter is assumed to be 33%, the energy increases as much as 10 mW×3 (efficiency)×0.9 ms=27 μWs per one time of transmission. A time TEQ required to equalize the increased energy with the energy reduced in the control device becomes 75 s obtained from 27 μWs=0.36 μW×TEQ. Specifically, the power consumption per one use of the remote-control can be compensated by 75 s. Since one day has 86400 s, if 1152 times of transmission are performed, the power consumption is offset. If considering a case where several ten times of control are normally conducted per one day, the effect on the power consumption even including the power consumption of the remote-control is large with the use of the present system.

Subsequently, another operation example of the control device according to this embodiment will be described with reference to FIG. 10 to FIG. 12. Although the calibration is performed by the correction operation prior to the high sensitivity state of the amplifier 40 in the operation example shown in FIG. 3 and FIG. 6, in the operation example shown in FIG. 10 to FIG. 12, the correction operation is surely conducted prior to a cycle of the high sensitivity state and the low sensitivity state. Namely, in the example, the correction operation, the high sensitivity state and the low sensitivity state are repeated as one cycle. There is conceivable a case in which the correction of high sensitivity state is required in a unit of one to several hours, for example, because the variation of elements forming the control device becomes large due to the surrounding environment. This operation example deals with such an environment. Note that since the configuration itself of the control device 1 and that of the remote-control device 2 are common to the configurations shown in FIG. 1 and FIG. 2, an overlapped explanation thereof will be omitted.

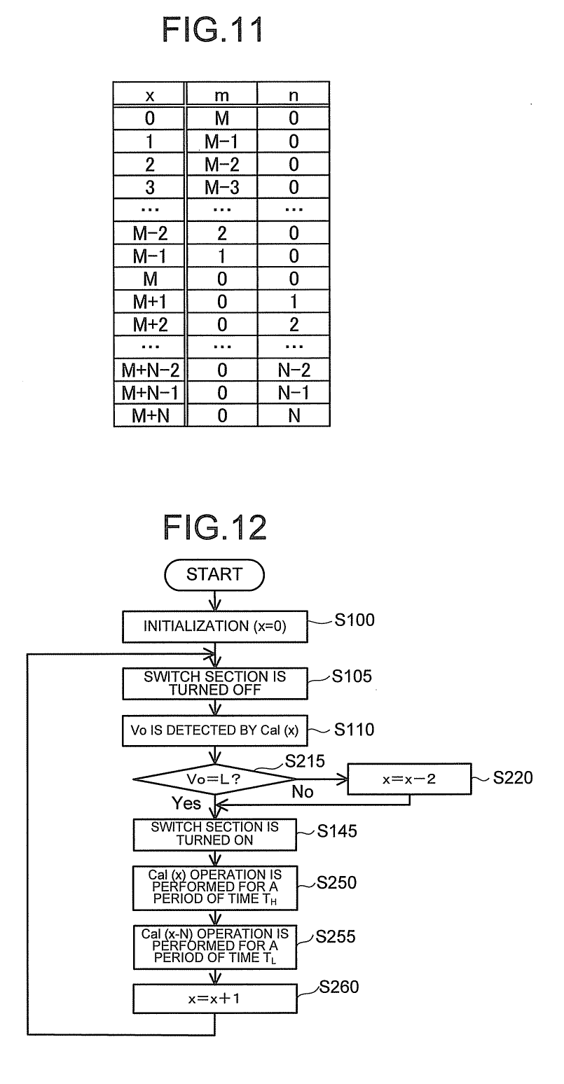

In this operation example, the memory 65 previously stores data shown in FIG. 11. Specifically, the memory 65 previously includes the value of variable x and its corresponding connection number m of M2_{b-1} to M2_{b-2} and connection number n of M3_{c-1} to M3_{c-2} as a table. This is to speed up the operation since the frequency of correction is increased. The relation among the variable x and the connection numbers m and n to be stored in the memory 65 is common to the correspondence described in FIG. 3. Specifically, when the variable x being the initial state is zero, the connection number m of M2_{b-1} to M2_{b-2} is set as M being the maximum value, and the connection number n of M3_{c-1} to M3_{c-2} is set as zero. Further, the values are combined so that the connection number m is decreased one by one at every time the variable x is increased one by one, and after the connection number m becomes zero, the connection number n is increased by one at a time. Accordingly, it becomes possible that the CAL control part 63 executes the correction operation only by reading the value of connection number from the memory 65 at the time of correction operation, which results in speeding up the operation.

As shown in FIG. 12, the CAL control part 63 initializes the value of variable x being held internally (S100). In an initial state, the sensitivity of amplifier 40 is set to be in a low state. Specifically, all of the switches SW_{b1} to SW_{b2} are turned on so that the connection number of M2_{b-1} to M2_{b-2} connected in parallel with M2 is made to be a maximum number (here, parallel number is set as M), and all of the switches SW_{c1} to SW_{c2} are turned off so that the connection number of M3_{c-1} to M3_{c-2} connected in parallel with M3 is made to be zero (namely, a state where only M3 exists is created). Such contents are previously stored in the memory 65, as shown in FIG. 11. Therefore, the CAL control part 63 collectively initializes the connection numbers m and n only by simply initializing the internal variable x.

When the variable x is initialized, the CAL control part 63 turns off the switch section 30 (S105). By turning off the switch section 30, the amplifier 40 is made to be in a state where no signal is input therein. Note that similar to the operation example shown in FIG. 3, the switch section 30 may also be connected so as to short-circuit the input to the amplifier 40.

When the switch section 30 is turned off, the CAL control part 63 detects the determination result made by the determination section 50 (S110).

As a result of detection, when the output Vo of the determination section 50 is not L (No in S215), the CAL control part 63 subtracts 2 from the variable x (S220). If the variable x becomes negative as a result of subtracting 2, the processing is continued on the assumption that the variable x is zero. Since the correction operation is integrated in the cycle of high sensitivity state and low sensitivity state in this operation example, even after the variable x is set to correspond to the high sensitivity state as a result of correction operation, the correction operation is conducted again after the high sensitivity state and the low sensitivity state are gone through. At this time, since it is inefficient if the correction operation is conducted from the initial state, a state of being back to the low sensitivity state by increasing/decreasing the connection numbers of M2_{b-1} to M2_{b-2} and M3_{c-1} to M3_{c-2} by two from the current state is set to be the initial state. The processing to subtract 2 from x ultimately means the processing to subtract 1 from x, which will be described later.

As a result of detection, when the output Vo of the determination section 50 is L (Yes in S215) and when the value of variable x is changed in step 120 (S220), the CAL control part 63 turns on the switch section 30 (S145). Accordingly, the rectifier 20 and the amplifier 40 are connected, and the control device 1 becomes a receiving state.

When the CAL control part 63 turns on the switch section 30, the amplifier control part 64 reads the connection numbers m and n corresponding to the current variable x from the memory 65, controls the corresponding switches SW_{b1} to SW_{b2} and SW_{c1} to SW_{c2} of the amplifier 40, and maintains the state for a predetermined period of time T_{H} (S250). The predetermined period of time T_{H} can be decided by the amplifier control part 64 based on a time signal from the clock 62.

Next, the amplifier control part 64 reads the connection numbers m and n corresponding to a value obtained by subtracting a predetermined number N from the current variable x from the memory 65, controls the corresponding switches SW_{b1} to SW_{b2} and SW_{c1} to SW_{c2} of the amplifier 40, and maintains the state for a predetermined period of time T_{L} (S255). The predetermined period of time T_{L} can also be decided by the amplifier control part 64 based on the time signal from the clock 62.

After the predetermined period of time T_{L} elapses, the amplifier control part 64 adds 1 to the variable x, and returns the processing to the CAL control part 63. The CAL control part 63 resumes the correction operation (S105).

In this operation example, the variable x is increased by one at a time until the amplifier 40 becomes in the high sensitivity state, and the correction operation, the high sensitivity state and the low sensitivity state are repeated during the period of time. Subsequently, when the amplifier 40 becomes in the high sensitivity state, 2 is subtracted from the variable x, and the operation is repeated again in such an order of the high sensitivity state, the low sensitivity state and the correction operation. Specifically, the amplifier 40 searches the connection numbers m and n constantly making the high sensitivity state, so that ultimately, its high sensitivity state is constantly maintained in a state being approximate to the best state. Therefore, even in a state where the surrounding environment is likely to change, it is possible to suppress the power consumption while constantly maintaining the high sensitivity.

Although there is few chance that the characteristic is largely changed due to a difference in the designation of order of the correction operation, the high sensitivity state and the low sensitivity state, there is a convenient order depending on determination criteria. For instance, if a setting after the determination is set to be the high sensitivity side as compared to the last time, it is preferable, in terms of the low power consumption, to provide a time zone of high sensitivity after the correction operation and provide a time zone of low sensitivity after that, because the change in the setting becomes small so that a transition due to the setting change becomes small. Regarding the decreased amount of power consumption realized by this operation example, if the correction operation time, the time during which the sensitivity is set to be the high sensitivity, and the time during which the sensitivity is set to be the low sensitivity are respectively set as T_{C}, T_{H} and T_{L}, the power consumption can be reduced to (T_{C}+T_{H})/(T_{C}+T_{H}+T_{L}) as compared to a case where the sensitivity is constantly set to be the high sensitivity state.

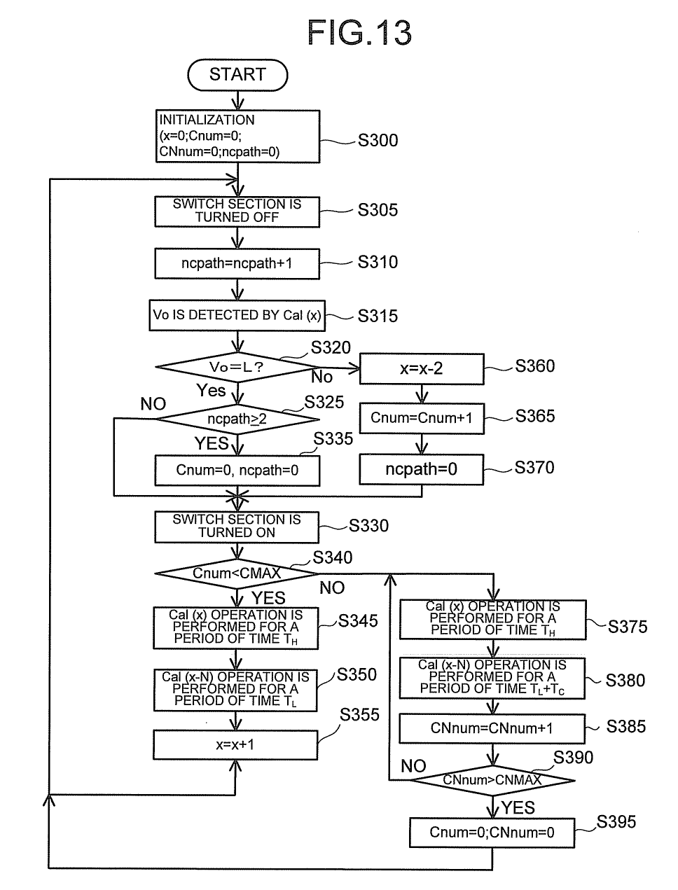

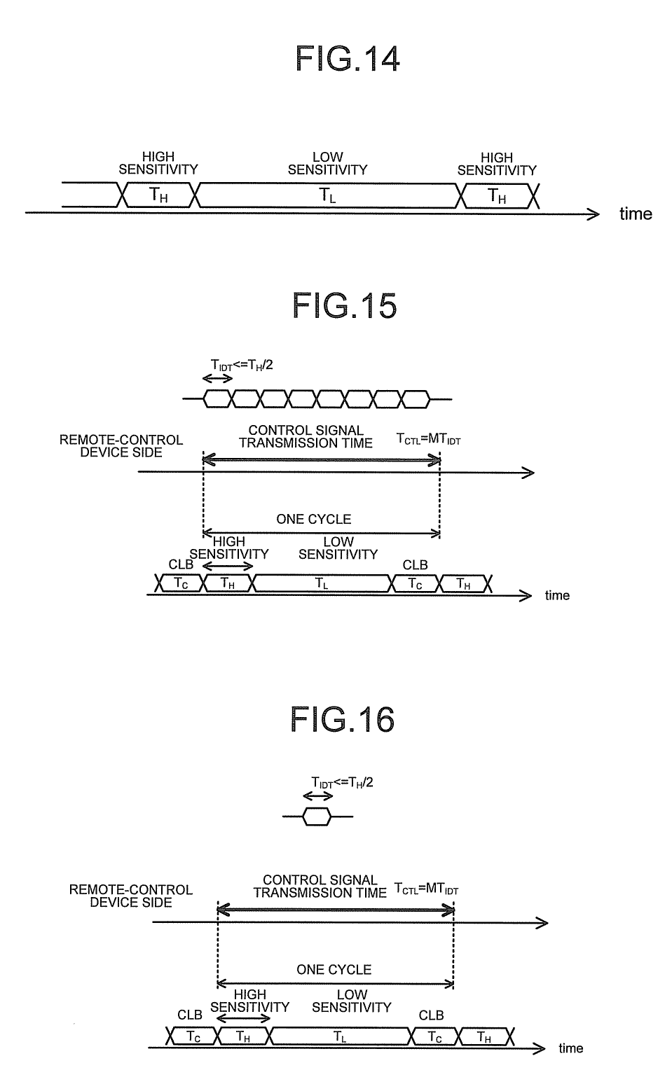

Subsequently, still another operation example of the control device according to this embodiment will be described with reference to FIG. 13, FIG. 14 and FIG. 10.

In the operation example shown in FIG. 3 and FIG. 5, the calibration is performed by the correction operation prior to the high sensitivity state of the amplifier 40, and in the operation example shown in FIG. 10 to FIG. 12, the correction operation is surely conducted prior to the cycle of the high sensitivity state and the low sensitivity state. In the operation example shown in FIG. 10 to FIG. 12, if T_{C} and T_{H} are set to be substantially the same period of time, the period of time T_{H} is equivalently doubled, so that the power consumption is about doubled as compared to that in the operation example shown in FIG. 5.

Accordingly, in the operation example to be described hereinbelow, by switching a mode in which three states of the calibration, the high sensitivity state and the low sensitivity state are set to be one cycle and a mode in which two states of the high sensitivity state and the low sensitivity state are set to be one cycle, the period of time T_{H} is relatively controlled. Concretely, when the power supply is turned on, the mode shown in FIG. 10 in which the three states are set as one cycle is used, and a high sensitivity point is sought by performing the correction operation. After the high sensitivity point is achieved, a sequence for executing two times of steps in which the variable x is decreased by two and increased by one is repeated. When the repetition reaches a predetermined number, it is determined that the surrounding environment does not change, and the mode is switched to the mode shown in FIG. 14 in which the two states of the high sensitivity state and the low sensitivity state are set as one cycle. After the mode is switched, the state is continued for a predetermined period of time, and then the mode is set to be back to the mode again in which the three states of the correction operation, the high sensitivity state and the low sensitivity state are set as one cycle.

Namely, in the operation example shown in FIG. 13, the mode in which the correction operation, the high sensitivity state and the low sensitivity state are set to be one cycle and the mode in which the high sensitivity state and the low sensitivity state are set to be one cycle are prepared, and both the modes are operated while being switched. Note that since the configuration itself of the control device 1 and that of the remote-control device 2 are common to the configurations shown in FIG. 1 and FIG. 2, an overlapped explanation thereof will be omitted.

Also in the example shown in FIG. 13, the variable x which can be used as an address, the connection number m of M2_{b-1} to M2_{b-2} and the connection number n of M3_{c-1} to M3_{c-2} are stored while being corresponded to one another in the memory 65, as shown in FIG. 11. Further, in the example shown in FIG. 13, the CAL control part 63 and the amplifier control part 64 include, as internal variables, Cnum, CNnum and ncpath in addition to x. The variable x is an address in the memory 65, the variable Cnum is a variable for determining presence/absence of transition of the high sensitivity point, ncpath is a variable used to reset Cnum when the high sensitivity point makes a transition, and CNnum is a variable for counting the two states of operation.

As shown in FIG. 13, the CAL control part 63 initializes the internal variables x, Cnum, CNnum and ncpath (S300). In an initial state, the sensitivity of amplifier 40 is set to be in a low state. For example, all of the switches SW_{b1} to SW_{b2} are turned on so that the connection number of M2_{b-1} to M2_{b-2} connected in parallel with M2 is made to be a maximum number (here, parallel number is set as M), and all of the switches SW_{c1} to SW_{c2} are turned off so that the connection number of M3_{c-1} to M3_{c-2} connected in parallel with M3 is made to be zero (namely, a state where only M3 exists is created).

When the internal variables are initialized, the CAL control part 63 turns off the switch section 30 (S305). By turning off the switch section 30, the amplifier 40 is made to be in a state where no signal is input therein.

When the switch section 30 is turned off, the CAL control part 63 adds 1 to the internal variable ncpath (S310), and detects the determination result made by the determination section 50 (S315).

As a result of detection, when the output Vo of the determination section 50 is L (Yes in S320), the CAL control part 63 determines whether or not the variable ncpath is equal to or larger than 2 (S320). When the variable ncpath is equal to or larger than 2 (Yes in S325), the CAL control part 63 initializes the variables Cnum and ncpath (S335).

As a result of detection, when the output Vo of the determination section 50 is not L (No in S320), the CAL control part 63 subtracts 2 from the variable x (S360), adds 1 to the variable Cnum (S365), and initializes the variable ncpath (S370).

When the variable ncpath is smaller than 2 (No in S325) and when the variables Cnum and ncpath are initialized (S335 and S370), the CAL control part 63 turns on the switch section 30 (S330). Accordingly, the rectifier 20 and the amplifier 40 are connected, and the control device 1 becomes a receiving state. In the first sequence, the output Vo is L and the variable ncpath is zero, so that the switch section 30 is turned on without any change being made.

When the switch section 30 is turned on, the CAL control part 63 determines whether or not the variable Cnum is larger than a maximum value CMAX (S340). When the variable Cnum is not larger than the maximum value CMAX (Yes in S340), the amplifier control part 64 reads the connection numbers m and n (values corresponding to the variable x) making the state of high sensitivity from the memory 65, controls the corresponding switches SW_{b1} to SW_{b2} and SW_{c1} to SW_{c2} of the amplifier 40, and maintains the state for a predetermined period of time T_{H} (S345).

Next, the amplifier control part 64 reads the connection numbers m and n (values corresponding to the variable x−N) making the state of low sensitivity from the memory 65, controls the corresponding switches SW_{b1} to SW_{b2} and SW_{c1} to SW_{c2} of the amplifier 40, and maintains the state for a predetermined period of time T_{L} (S350).

After the predetermined period of time T_{L} elapses, the amplifier control part 64 adds 1 to the variable x (S355), returns the processing to the CAL control part 63, and resumes the correction operation (S305).

Meanwhile, when the variable Cnum is larger than the maximum value CMAX (No in S340), the amplifier control part 64 reads the connection numbers m and n (values corresponding to the variable x) making the state of high sensitivity from the memory 65, controls the corresponding switches SW_{b1} to SW_{b2} and SW_{c1} to SW_{c2} of the amplifier 40, and maintains the state for a predetermined period of time T_{H} (S375).

Next, the amplifier control part 64 reads the connection numbers m and n (values corresponding to the variable x−N) making the state of low sensitivity from the memory 65, controls the corresponding switches SW_{b1} to SW_{b2} and SW_{c1} to SW_{c2} of the amplifier 40, and maintains the state for a predetermined period of time T_{L} (S380).

After the predetermined period of time T_{L} elapses, the CAL control part 63 determines whether or not the variable Cnum is equal to or larger than the maximum value CMAX (S390). When the variable Cnum is smaller than the maximum value CMAX, the amplifier control part 64 reads the connection numbers m and n (values corresponding to the variable x) making the state of high sensitivity from the memory 65, and executes the operations in the high sensitivity state and the low sensitivity state and adding processing on Cnum (S375 to S385). When the variable CNnum is equal to larger than a maximum value CNMAX, the CAL control part 63 initializes the variables Cnum and CNnum (S395), and resumes the correction operation (S305). Here, CNnum represents the maximum number of times at which the mode in which the high sensitivity state and the low sensitivity state are set as one cycle is consecutively executed. This value is previously set.

In the control device according to this embodiment, the operation shown in FIG. 10 in which the correction operation, the high sensitivity state and the low sensitivity state are set to be one cycle and the operation shown in FIG. 14 in which the high sensitivity state and the low sensitivity state are set to be one cycle are operated while being switched. For instance, in a case where the variation or fluctuation of the elements of M1 to M4 is large due to the surrounding environment, the operation shown in FIG. 10 is executed in order to increase the frequency of the correction operation. On the other hand, in a case where the high sensitivity state is stable, the operation shown in FIG. 14 in which the correction operation is omitted is executed. If the correction operation is omitted, the power consumption can be suppressed, so that by combining the operation shown in FIG. 10 and the operation shown in FIG. 14, it becomes possible to further suppress the power consumption.

Here, a relation among the instruction signal to be transmitted by the remote-control device 2 and respective operations of the correction operation, the high sensitivity state and the low sensitivity state of the control device 1 will be described.

Also in this operation example, there exists two operating states of the high sensitivity state and the low sensitivity state, similar to the example of the remote-control device shown in FIG. 7 to FIG. 9, so that it is possible to suppress power consumption also at the remote-control device side in accordance with a distance between the remote-control device and the control device. However, if the distance between the remote-control device and the control device is relatively long when the operation is performed by setting the correction operation, the high sensitivity state and the low sensitivity state as one cycle, since the control device 1 cannot perform the reception during the period of time of the correction operation, there is a need to transmit the instruction signal having a length at which the signal can be surely received in the high sensitivity state. Accordingly, as shown in FIG.15, the total period of time of the correction operation period of time T_{C}+the high sensitivity state T_{H}+the low sensitivity state T_{L} is only required to be set as the control signal transmission time T_{CTL}.

Meanwhile, when the distance between the remote-control device and the control device is short, if the instruction signal is transmitted for a period of time longer than the correction operation period of time T_{C}, the control device can surely receive the instruction signal.

### Second Embodiment

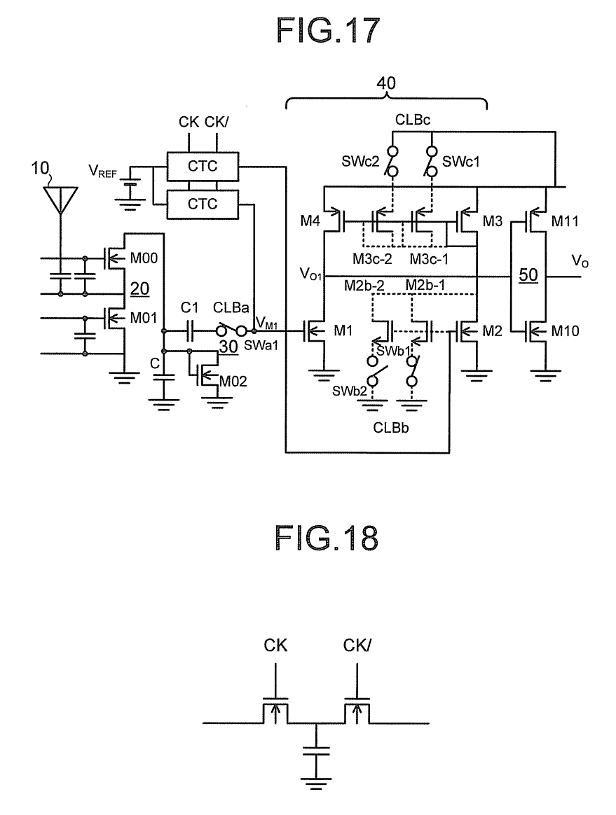

Next, a control device according to another embodiment will be described in detail with reference to FIG. 17 and FIG. 18. The control device according to this embodiment corresponds to the control device according to the first embodiment in which the current source is replaced with a charge transfer control section (CTC), so that the common elements are designated by the same reference numerals and an overlapped explanation thereof will be omitted.

In the control device 1 shown in FIG. 2, the threshold voltage of M1 is increased by using the current sources I1 and I2 in order to realize the high sensitivity, but, in the control device according to this embodiment, the threshold voltage of M1 is set by the charge transfer control (CTC).

The CTC has a function of transferring charges stored in a capacitor included therein, and performs equivalently the same operation as that of a resistance, so that it can be replaced with a resistor. As shown in FIG. 18, the CTC includes a pair of transfer transistor and capacitor. Accordingly, the need to steadily flow the current is eliminated, and the current is supplied only when the input is made, so that the power consumption can be suppressed compared to that in the control device according to the first embodiment. Note that the operation example of the first embodiment (FIG. 3, FIG. 6, FIG. 10, FIG. 12 and FIG. 13) can also be applied to the control device and a remote-control device according to the second embodiment.

It should be noted that the present invention is not limited only to the aforementioned embodiments and their operation examples. For instance, the explanation of the above embodiments was made in which the connection numbers making the high sensitivity state and the low sensitivity state are stored in the memory in the operation example shown in FIG. 3, and all the combinations of MOSFETs connected in parallel are stored in the memory in the operation example shown in FIG. 12 and FIG. 13, but, it is not limited to this. Specifically, the table shown in FIG. 11 may be stored in the memory in the operation example shown in FIG. 3, or the same contents as those of the operation example shown in FIG. 3 may be stored in the memory in the operation example shown in FIG. 12 and FIG. 13. In either case, the same effect can be achieved. In like manner, the present invention is not limited to the above-described embodiments as they are, but may be embodied with components being modified in a range not departing from the contents thereof at the stage of implementation. Further, various inventions can be formed by correctly combining a plurality of components disclosed in the above-described embodiments. For example, some of all the components shown in the embodiments may be deleted. Further, components ranging across different embodiments can be combined correctly. Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A control device, comprising:
a rectifier to rectify a received signal;
an amplifier having an amplifying element to amplify the signal rectified by the rectifier and an assisting element being connected to the amplifying element to assist the amplifying element;
a determination unit to determine presence or absence of the signal amplified by the amplifier; and
a controller to control the connection of the assisting element with the amplifying element at a predetermined timing.

2. The device of claim 1,
wherein the amplifier has a plurality of the assisting elements; and
wherein the controller controls a connection number of the assisting element with the amplifying element at the predetermined timing.

3. The device of claim 1,
wherein the amplifier has a plurality of the assisting elements; and
wherein the controller further conducts correction control for searching an optimum first connection number of the assisting element with the amplifying element for enhancing a sensitivity of the amplifier and controls the connection number of the assisting element with the amplifying element to be either of the first connection number and a second connection number other than the first connection number at the predetermined timing.

4. The device of claim 3, further comprising,
a switch connected between an output of the rectifier and an input of the amplifying element of the amplifier,
wherein the controller turns off the switch while searching the optimum first connection number.

5. The device of claim 3,
wherein the controller controls the connection number of the assisting element with the amplifying element by alternately selecting either of the first connection number and the second connection number.

6. The device of claim 3,
wherein the controller executes the correction control, a control to set the connection number to the first connection number and a control to set the connection number to the second connection number as a cycle.

7. A control method of a control device including a rectifier to rectify a received signal, an amplifier having an amplifying element to amplify the signal rectified by the rectifier and an assisting element being connected to the amplifying element to assist the amplifying element, a determination unit to determine presence or absence of the signal amplified by the amplifier, and a controller to control the connection of the assisting element with the amplifying element at a predetermined timing, the control method, comprising:
searching, with the controller, an optimum first connection number of the assisting element with the amplifying element for enhancing a sensitivity of the amplifier;
controlling, with the controller, a connection number of the assisting element with the amplifying element to be the first connection number at the predetermined timing; and
controlling, with the controller, the connection number of the assisting element with the amplifying element to be a second connection number other than the first connection number.
